(19) United States
(12) Patent Application Publication
(10) Pub. No.: US 2025/0183226 A1
(43) Pub. Date: Jun. 5, 2025

(54) SEMICONDUCTOR DEVICES AND SYSTEMS INCLUDING STACKED LOGIC DIES

(71) Applicant: Advanced Micro Devices, Inc., Santa Clara, CA (US)

(72) Inventors: Russell Schreiber, Austin, TX (US); John Wuu, Ft. Collins, CO (US); Spence Oliver, Austin, TX (US)

(73) Assignee: Advanced Micro Devices, Inc., Santa Clara, CA (US)

(21) Appl. No.: 18/526,418

(22) Filed: Dec. 1, 2023

(51) Int. Cl. H01L 25/065; H01L 23/00; H01L 23/48

(52) U.S. Cl. CPC H01L 25/0652; H01L 23/481; H01L 24/08; H01L 24/80; H01L 2224/08146; H01L 2224/80895; H01L 2924/1431

(57) ABSTRACT

A semiconductor device includes a first logic die comprising: a clock source configured to generate a clock signal; and a first clock mesh for receiving the clock signal from the clock source. The device includes a second logic die stacked over the first logic die, the second logic die comprising: a second clock mesh for receiving the clock signal from the clock source. The device includes a plurality of conductive connections between the first clock mesh and the second clock mesh to transmit the clock signal from the first clock mesh to the second clock mesh. Various other methods and systems are also disclosed.

### BACKGROUND

Computer processors are integrated circuits that execute instructions and perform computing tasks. To conserve space, reduce power consumption, and/or improve processing speed, some processors include two stacked logic dies that are assembled to communicate with each other. The stacked logic dies perform computing tasks together or separately.

At a basic level, operation of a computer processor includes transmitting, storing, and recalling data on a bit-by-bit basis. Some modern processors can perform up to billions of these operations every second, or at speeds of one or more gigahertz. Clock signals are electrical pulses that are often used by processors to indicate when the components of the processor are to perform the operations.

### BRIEF DESCRIPTION OF THE DRAWINGS

The accompanying drawings illustrate a number of example implementations and are a part of the specification. Together with the following description, these drawings demonstrate and explain various principles of the present disclosure.

FIG. 1 is a diagram of a system including a computing device with stacked logic dies, according to at least one example implementation of the present disclosure.

FIG. 2 is a diagram of a semiconductor device, according to at least one example implementation of the present disclosure.

FIG. 3 is a diagram of an example implementation of a state storage element integrated into or with a computing device, according to at least one example implementation of the present disclosure.

FIG. 4 is a flow diagram illustrating a method of fabricating a semiconductor device, according to one or more implementations of the present disclosure.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to semiconductor devices, computer systems, and methods that employ two logic dies (e.g., processor dies) stacked over each other. The logic dies each include a clock mesh, and a plurality of conductive connections are used to short the two clock meshes to each other for transmitting a clock signal between the clock meshes.

Clock skew occurs when a clock signal from a clock source reaches different active components (e.g., state storage elements) at different times, resulting in activation of these components at different times. Clock skew can occur due to divergence when a clock signal reaches one component after passing through a small number of stages and another component after passing through a larger number of stages, resulting in a longer pathway with potentially additional resistance and/or impedance. Clock skew can result in challenges in setup and hold operations of the semiconductor devices, which can cause performance problems (e.g., delayed or slowed operation) or require mitigation techniques (e.g., installation of buffers, etc.) to address.

The plurality of conductive connections between the clock meshes in stacked logic dies can inhibit (e.g., reduce, minimize, or eliminate) clock skew between the two dies. In other words, the clock signal can pass through one clock mesh and across the interface between the two logic dies through the plurality of conductive connections. The clock signal is passed (e.g., directly passed, shorted) by the conductive connections to the other clock mesh for use by the other die. This passage of the clock signal occurs with little or no divergence. Therefore, the clock signal can reach the active components of both logic dies with little or no clock skew.

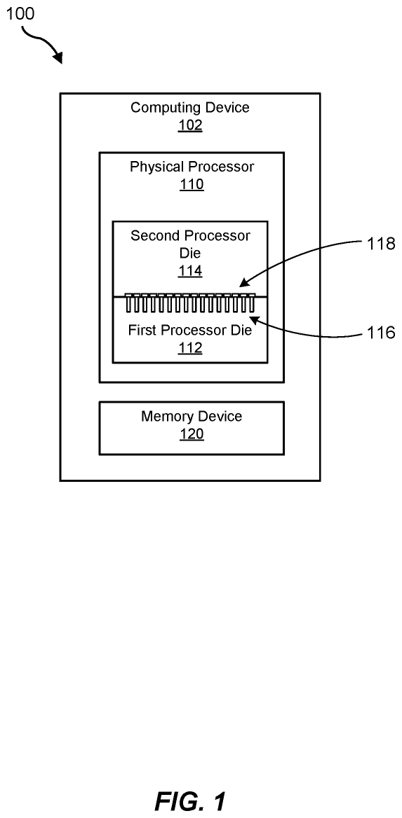

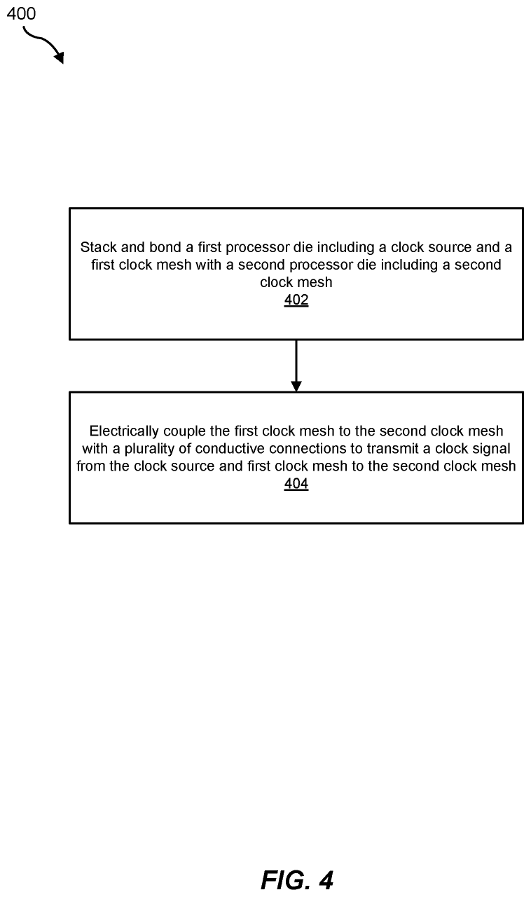

The following will provide, with reference to FIGS. 1-3, detailed descriptions of example semiconductor devices, computer systems including semiconductor devices, and components thereof, according to various examples of the present disclosure. Detailed descriptions of methods of fabricating a semiconductor device will also be provided in connection with FIG. 4.

In some aspects, the techniques described herein relate to a semiconductor device that includes a first logic die and a second logic die stacked over the first logic die. The first logic die includes a clock source configured to generate a clock signal and a first clock mesh for receiving the clock signal from the clock source. The second logic die includes a second clock mesh for receiving the clock signal from the clock source. The semiconductor device also includes a plurality of conductive connections between the first clock mesh and the second clock mesh to transmit the clock signal from the first clock mesh to the second clock mesh.

In some aspects, the techniques described herein relate to a semiconductor device, wherein the plurality of conductive connections includes conductive vias electrically connecting the first clock mesh to the second clock mesh.

In some aspects, the techniques described herein relate to a semiconductor device, wherein the conductive vias are positioned in and pass through at least a portion of the first logic die.

In some aspects, the techniques described herein relate to a semiconductor device, wherein the conductive vias are electrically connected to respective conductive bond pads.

In some aspects, the techniques described herein relate to a semiconductor device, wherein the first logic die includes the conductive vias and the second logic die includes the conductive bond pads.

In some aspects, the techniques described herein relate to a semiconductor device, wherein the clock source includes a phase-locked loop clock source.

In some aspects, the techniques described herein relate to a semiconductor device, wherein the second logic die further includes a local clock source configured to generate a test clock signal for testing of the second logic die separate from the first logic die.

In some aspects, the techniques described herein relate to a semiconductor device, wherein the second logic die further includes a tri-state driver between the local clock source and the second clock mesh.

In some aspects, the techniques described herein relate to a semiconductor device, wherein the plurality of conductive connections includes at least one hundred conductive connections between the first clock mesh and the second clock mesh.

In some aspects, the techniques described herein relate to a semiconductor device, wherein the plurality of conductive connections includes at least one thousand conductive connections between the first clock mesh and the second clock mesh.

In some aspects, the techniques described herein relate to a semiconductor device, wherein: the first logic die further includes: a first plurality of state storage elements configured for receiving the clock signal from the first clock mesh; and at least one first level of gating between the first clock mesh and the first plurality of state storage elements; and the second logic die further includes: a second plurality of state storage elements configured for receiving the clock signal from the second clock mesh; and at least one second level of gating between the second clock mesh and the second plurality of state storage elements.

In some aspects, the techniques described herein relate to a semiconductor device, wherein: the first plurality of state storage elements includes a first plurality of flip-flop elements; and the second plurality of state storage elements includes a second plurality of flip-flop elements.

In some aspects, the techniques described herein relate to a semiconductor device, wherein the first logic die further includes a tri-state driver between the clock source and the first clock mesh, wherein the tri-state driver is deactivated during testing of the first logic die separate from the second logic die and is activated during operation of the first logic die and second logic die stacked over the first logic die to boost the generated clock signal for use by both the first logic die and the second logic die.

In some aspects, the techniques described herein relate to a computer system that includes a memory device configured to store computer-executable instructions and a semiconductor device in communication with the memory device and configured to execute the computer-executable instructions. The semiconductor device includes a first logic die and a second logic die stacked over the first logic die. The first logic die includes: a clock source configured to generate a clock signal; a first plurality of state storage elements; and a first clock mesh for distributing the generated clock signal from the clock source to the first plurality of state storage elements. The second logic die includes: a second plurality of state storage elements; and a second clock mesh for distributing the clock signal from the clock source to the second plurality of state storage elements. The semiconductor device also includes a plurality of conductive connections between the first clock mesh and the second clock mesh to transmit the clock signal from the first clock mesh to the second clock mesh.

In some aspects, the techniques described herein relate to a system, wherein the plurality of conductive connections includes conductive vias passing through at least a portion of the first logic die and conductive bond pads of the second logic die.

In some aspects, the techniques described herein relate to a system, wherein the first plurality of state storage elements includes a first plurality of flip-flop elements and the second plurality of state storage elements includes a second plurality of flip-flop elements.

In some aspects, the techniques described herein relate to a system, wherein the plurality of conductive connections includes an array of at least one hundred conductive connections.

In some aspects, the techniques described herein relate to a method of fabricating a logic device, the method including: stacking and bonding a first logic die including a clock source and a first clock mesh with a second logic die including a second clock mesh; and electrically coupling the first clock mesh to the second clock mesh with a plurality of conductive connections to transmit a clock signal from the clock source and first clock mesh to the second clock mesh.

In some aspects, the techniques described herein relate to a method, wherein electrically coupling the first clock mesh to the second clock mesh with the plurality of conductive connections includes electrically shorting the first clock mesh to the second clock mesh with an array of conductive connections.

In some aspects, the techniques described herein relate to a method, wherein electrically shorting the first clock mesh to the second clock mesh with an array of conductive connections includes electrically shorting the first clock mesh to the second clock mesh with an array of at least one hundred conductive vias passing through at least a portion of the first logic die.

FIG. 1 illustrates an example system 100 involving a computing device 102. Examples of the computing device 102 include, without limitation, memory devices, processing devices, Central Processing Units (CPUs), Graphics Processing Units (GPUs), microprocessors, microcontrollers, Field-Programmable Gate Arrays (FPGAs), Application-Specific Integrated Circuits (ASICs), Systems-on-a-Chip (SoCs), Static Random-Access Memory (SRAM) devices, Random Access Memory (RAM) devices, Read Only Memory (ROM) devices, flash memory devices, Hard Disk Drives (HDDs), Solid-State Drives (SSDs), optical disk drives, caches, routers, switches, hubs, modems, bridges, repeaters, gateways (such as Broadband Network Gateways (BNGs)), network devices, client devices, laptops, tablets, desktops, servers, cellular phones, Personal Digital Assistants (PDAs), multimedia players, embedded systems, wearable devices, gaming consoles, portions of one or more of the same, variations or combinations of one or more of the same, and/or any other suitable device.

As illustrated in FIG. 1, the computing device 102 includes and/or represents a physical processor 110 in communication with a memory device 120. In some implementations, the physical processor 110 includes a stack of a first logic die 112 and a second logic die 114 over (e.g., bonded to) the first logic die 112.

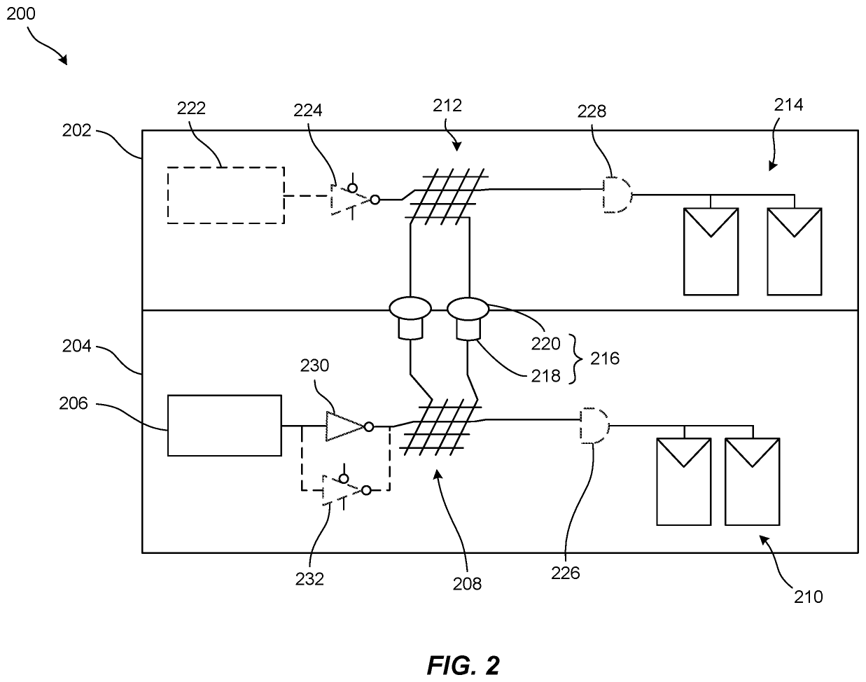

As further explained below with reference to FIG. 2, the first logic die 112 includes a clock source and first clock mesh for distributing a clock signal from the clock source to active components (e.g., to a first plurality of state storage elements, such as flip-flops) of the first logic die 112. The second logic die 114 includes a second clock mesh for distributing the clock signal to active components (e.g., to a second plurality of state storage elements, such as flip-flops) of the second logic die 114.

In some examples, the first clock mesh and the second clock mesh are electrically coupled (e.g., shorted, directly electrically coupled) to each other with a plurality of conductive connections, such as with a plurality of conductive vias 116, conductive pads 118, combinations thereof, and/or the like. For example, the first clock mesh and second clock mesh are electrically coupled to each other with an array of more than one hundred conductive connections, more than five hundred conductive connections, more than one thousand conductive connections, or multiple thousands of conductive connections. The specific number of conductive connections for a given implementation depends on the size and capacity of the physical processor 110, space constraints, manufacturing capabilities, and/or other possible considerations.

By way of example, the conductive vias 116 can pass through at least a portion of the first logic die 112, and the conductive pads 118 respectively coupled to the conductive vias 116 can be in or on the second logic die 114. In another example, the conductive vias 116 can pass through at least a portion of the second logic die 114, and the conductive pads 118 can be in or on the first logic die 112. Alternatively, both the first logic die 112 and second logic die 114 can include conductive vias 116 that are electrically coupled to each other. In additional implementations, both the first logic die 112 and second logic die 114 can include conductive pads 118 that are electrically coupled to each other.

The conductive vias 116 and/or conductive pads 118 are electrically coupled (e.g., directly coupled) to the first clock mesh and to the second clock mesh to electrically short the first clock mesh and second clock mesh to each other at many (e.g., more than one hundred, more than five hundred, more than one thousand, multiple thousands of, etc.) locations. This arrangement of many conductive connections inhibits (e.g., reduces, minimizes, or eliminates) clock skew between the first logic die 112 and second logic die 114, such as by redundantly passing the clock signal originating at the clock source from the first clock mesh to the second clock mesh for transmission of the clock signal to active components of the first logic die 112 and second logic die 114.

Examples of the physical processor 110 include, without limitation, CPUs, GPUs, microprocessors, microcontrollers, FPGAs, ASICs, SoCs, combinations or variations of one or more of the same, and/or any other type of suitable processing device. In some examples, the physical processor 110 can include and/or represent any type or form of hardware-implemented processor capable of executing computer-readable instructions stored in the memory device 120.

In some examples, the memory device 120 can include and/or represent any type or form of volatile or non-volatile storage device or computer-readable medium capable of storing data and/or computer-readable instructions. In one example, the memory device 120 includes and/or represents an SRAM device. In some examples, the memory device 120 maintains and/or stores data, including executable instructions for execution by the physical processor 110.

The term “computer-readable medium,” as used herein, can generally refer to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

Many other devices or subsystems can be connected to the system 100 in FIG. 1. Conversely, all of the components and devices illustrated in FIG. 1 need not be present to practice the implementations described and/or illustrated herein. The devices and subsystems referenced above can also be interconnected in different ways from that shown in FIG. 1. The system 100 can also employ any number of software, firmware, and/or hardware configurations. For example, one or more of the example implementations disclosed herein can be encoded as a computer program (also referred to as computer software, software applications, computer-readable instructions, and/or computer control logic) on a computer-readable medium.

FIG. 2 is a diagram of a semiconductor device 200 (e.g., a processor device) including a first logic die 202 (e.g., a first processor die) and a second logic die 204 (e.g., a second processor die) stacked over and bonded to the first logic die 202. In some implementations, the first logic die 202 includes a clock source 206 configured to generate a clock signal for operation of both the first logic die 202 and second logic die 204. The first logic die 202 also includes a first clock mesh 208 that receives the clock signal from the clock source 206 and distributes the clock signal to other components of the first logic die 202, such as a first plurality of state storage elements 210.

In some implementations, the second logic die 204 includes a second clock mesh 212 that receives the clock signal from the clock source 206 through the first clock mesh 208 and distributes the clock signal to other components of the second logic die 204, such as a second plurality of state storage elements 214. In some implementations, the first clock mesh 208 and the second clock mesh 212 each include a grid or net of metal or other conductive material.

In some examples, the first clock mesh 208 and the second clock mesh 212 are electrically coupled to (e.g., shorted to) each other using a plurality of conductive connections 216. For example, each of the conductive connections 216 can include a conductive via 218 (e.g., a so-called “through-silicon via” or “TSV”) electrically coupled to a respective conductive bond pad 220. In the example shown in FIG. 2, the first logic die 202 includes an array of conductive vias 218 and the second logic die 204 includes an array of conductive bond pads 220 corresponding to and electrically coupled to the conductive vias 218. The conductive vias 218 pass through at least a portion of the first logic die 202, such as a portion including the first clock mesh 208 and a surface of the first logic die 202 abutting against the second logic die 204.

Two conductive connections 216 are illustrated in FIG. 2 for simplicity. However, the number of conductive connections 216 depends on the size of the overlapping portion of the first clock mesh 208 and second clock mesh 212. In some examples, the semiconductor device 200 includes tens of conductive connections 216, at least one hundred conductive connections 216, at least five hundred conductive connections 216, at least one thousand conductive connections 216, or multiple thousands of conductive connections 216 between the first clock mesh 208 and second clock mesh 212.

The clock source 206 is a device or element that generates a clock signal for use by other components of the semiconductor device 200, such as for synchronizing operation of the components of the semiconductor device 200. By way of non-limiting examples, the clock source 206 can be implemented as a phase-locked loop (PLL) circuit, a frequency-locked loop (FLL) circuit, a delay-locked loop (DLL) circuit, or the like. In some implementations, the clock source 206 generates the clock signal and transmits the clock signal to the first plurality of state storage elements 210 through the first clock mesh 208. The clock signal is also transmitted to the second plurality of state storage elements 214 through the first clock mesh 208, the plurality of conductive connections 216, and the second clock mesh 212. In some examples, at least some of the first state storage elements 210 of the first logic die 202 can transmit data to and/or from at least some of the second state storage elements 214 of the second logic die 204. The transmission of the data between the first state storage elements 210 and the second state storage elements 214 can include substantially synchronized setup operations and hold operations.

In some examples, the term “substantially” in reference to a given parameter, property, or condition, refers to a degree that one skilled in the art would understand that the given parameter, property, or condition is met with a small degree of variance, such as within acceptable manufacturing tolerances. For example, a parameter that is substantially met can be at least about 90% met, at least about 95% met, at least about 99% met, or fully met.

In some implementations, the second logic die 204 optionally includes a local clock source 222. The local clock source 222 generates a test clock signal for testing the second logic die 204 separate from the first logic die 202, such as prior to the second logic die 204 being bonded to the first logic die 202. For example, the second logic die 204 can be tested for operability at a wafer level, prior to the wafer being diced and/or stacked over the first logic die 202, using the local clock source 222. Testing at the wafer level enables cost reduction in manufacturing by scrapping only the single second logic die 204 if it is not functional to a given specification, rather than scrapping the entire semiconductor device 200 with both the first logic die 202 and second logic die 204 if only the second logic die 204 fails.

As illustrated in the example of FIG. 2, the local clock source 222, if present, is connected to the second clock mesh 212 through a tri-state driver 224. The tri-state driver 224, when activated, allows the local clock signal to pass to the second clock mesh 212 and ultimately to the second plurality of state storage elements 214 for testing, but blocks use of the local clock source 222 during normal operation of the second logic die 204 (e.g., during operation of the second logic die 204 together with the first logic die 202 in the semiconductor device 200). Blocking use of the local clock source 222 during normal operation of the second logic die 204 saves power and inhibits (e.g., reduces, minimizes, or eliminates) clock skew between the first logic die 202 and second logic die 204 that might otherwise exist if the local clock source 222 and the clock source 206 were used simultaneously.

In some examples, optionally, the first logic die 202 includes at least one first level of gating 226 between the first clock mesh 208 and the first plurality of state storage elements 210. Likewise, the second logic die 204 can include at least one second level of gating 228 between the second clock mesh 212 and the second plurality of state storage elements 214. The first and second levels of gating 226, 228 are used to switch off circuits (e.g., portions of the first and second plurality of state storage elements 210, 214, buses, bridges, controllers, etc.), such as for reducing a power consumption of the first logic die 202 and/or second logic die 204.

In the example illustrated in FIG. 2, the first logic die 202 includes one or more gain stages 230 between the clock source 206 and the first clock mesh 208, which strengthen and/or clarify the clock signal generated by the clock source 206 prior to reaching the first clock mesh 208. The one or more gain stages 230 are represented in FIG. 2 as an inverter. The inverter of FIG. 2 represents one or more inverters or other signal driving elements that can be present in the form of a tree of multiple inverters or other signal driving elements and/or multiple inverters or other signal driving elements in series and/or parallel.

Optionally, the first logic die 202 can also include a programmable driver 232 in conjunction with (e.g., parallel with) the one or more gain stages 230. For example, the clock source 206 together with the one or more gain stages 230 and programmable driver 232 of FIG. 2 are sized and powered to drive operation of both the first logic die 202 and the second logic die 204 when stacked and operated together. When the first logic die 202 is to be operated alone, without also operating the second logic die 204 (e.g., in another implementation that does not include the second logic die 204, during testing of the first logic die 202, etc.), the combination of the one or more gain stages 230 and programmable driver 232 would therefore be oversized. In this case, the programmable driver 232 is disabled, reducing the power consumption of the circuit to the power that drives operation of only the first plurality of state storage elements 210. On the other hand, if the clock source 206 is to transmit the clock signal to both the first plurality of state storage elements 210 and second plurality of state storage elements 214 (e.g., as illustrated in FIG. 2), the programmable driver 232 is enabled, increasing the power consumption of the circuit to the power sufficient to drive operation of both the first plurality of state storage elements 210 and second plurality of state storage elements 214.

When present, in some implementations, the programmable driver 232 can be or include a tri-state driver. The programmable driver 232 can be a fuse-programmable driver 232 enabled when the second logic die 204 is coupled to, and is to be driven by, the first logic die 202. When the first logic die 202 is to be operated alone (e.g., without the second logic die 204), the fuse-programmable driver 232 is disabled to reduce power consumption, heat generation, etc.

In some implementations, at least some of the first plurality of state storage elements 210 of the first logic die 202 are in communication with at least some of the second plurality of state storage elements 214. As these components pass data (e.g., bits) between each other, reducing clock skew can be helpful to improve or maintain processing performance, such as during setup or hold operations. Accordingly, some aspects of the present disclosure reduce clock skew between the first plurality of state storage elements 210 and the second plurality of state storage elements 214 to improve or maintain performance.

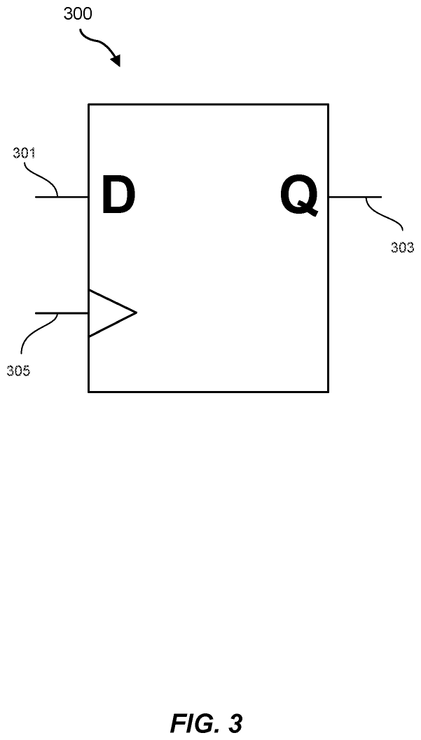

FIG. 3 illustrates an example state storage element 300, in the form of a flip-flop having multiple external inputs and/or outputs. The state storage element 300 can be used as any of the first or second plurality of state storage elements 210, 214 described above. In some examples, the state storage element 300 represents or includes a one-bit memory device whose output state can be changed by various input signals applied to its inputs such as a d-type flip-flop, a t-type flip-flop, a jk-type flip-flop, a latch, portions of one or more of the same, variations or combinations of one or more of the same, and/or any other suitable device. In some examples, the state storage element 300 represents or includes a master-slave flip-flop (e.g., built from two back-to-back sequential elements such as latches). In some examples, the state storage element 300 represents or includes an edge-triggered memory device whose output state changes on a clock edge. In at least one example, the state storage element 300 represents or includes a positive-edge triggered, static, or quasi-static d-type flip-flop. In the example illustrated in FIG. 3, the state storage element 300 includes an external data input 301, an external data output 303, and an external clock input 305 (e.g., for receiving a clock signal from the clock source 206 and/or from the local clock source 222). In some examples, the state storage element 300 is configured to sample a state of a signal at the external data input 301, issue the sampled state at the external data output 303, and/or store the sampled state until replacement by another.

In some examples, the various circuits, components, and/or devices described in connection with FIGS. 1-3 can include and/or represent one or more additional or functionally equivalent circuits, components, devices, and/or features that are not necessarily illustrated and/or labeled in FIGS. 1-3. For example, such circuits, components, and/or devices can also include and/or represent additional or functionally equivalent analog and/or digital circuitry, onboard logic, transistors, resistors, capacitors, diodes, inductors, switches, registers, flip-flops, connections, traces, buses, semiconductor (e.g., silicon) devices and/or structures, storage devices, circuit boards, housings, combinations or variations of one or more of the same, and/or any other suitable components. One or more of these additional or functionally equivalent circuits, components, and/or devices can be inserted and/or applied between any of the existing circuits components, and/or devices illustrated in FIGS. 1-3 consistent with the aims and/or objectives provided herein. Accordingly, the communicative and/or electrical couplings described with reference to FIGS. 1-3 can be direct connections with no intermediate components, devices, and/or nodes or indirect connections with one or more intermediate components, devices, and/or nodes.

FIG. 4 is a flow chart illustrating a method 400 of fabricating a semiconductor device, according to one or more examples of the present disclosure. At operation 402, a first logic die is stacked and bonded with a second logic die. The first logic die includes a clock source and a first clock mesh and the second logic die includes a second clock mesh. Operation 402 can be performed in a variety of ways. For example, the first logic die can be a base die mounted to an underlying support structure (e.g., a printed circuit board, an interposer, a heat sink, etc.) and the second logic die can be mounted over and bonded to a top surface of the first logic die. The first logic die and the second logic die can be a same geometrical size (e.g., in length and width) as each other, or the second logic die can be a different size (e.g., smaller) than the first logic die. In additional implementations, the second logic die can be a base die and the first logic die can be mounted over and bonded to a top surface of the second logic die. In some examples, the first logic die and the second logic die can have a same or similar technology level and/or type (e.g., technology generation and/or version). In additional examples, the first logic die and the second logic die can have a different technology level and/or type.

At operation 404, the first clock mesh is electrically coupled (e.g., shorted) to the second clock mesh with a plurality of conductive connections to transmit a clock signal from the clock source and first clock mesh to the second clock mesh. Operation 404 can be performed in a variety of ways. For example, the plurality of conductive connections can include a plurality of conductive vias (e.g., TSVs) in the first logic die and a plurality of conductive bond pads in the second logic die respectively coupled to the conductive vias. In additional examples, the conductive bond pads can be in the first logic die and the conductive vias can be in the second logic die. Alternatively, both of the first and second logic dies can include conductive vias or both of the first and second logic dies can include conductive bond pads.

In some implementations, the plurality of conductive connections extend across an interface (e.g., a bonding interface) between the first logic die and the second logic die. The plurality of conductive connections can include an array of conductive connections. The array can include at least one hundred, at least five hundred, at least one thousand, or multiple thousands of conductive connections between the first clock mesh and the second clock mesh to inhibit (e.g., reduce, minimize, or eliminate) potential clock skew between the first clock mesh and the second clock mesh.

Accordingly, the present disclosure includes computer systems, semiconductor devices, and methods that employ stacked logic dies that include respective clock meshes shorted with each other using a plurality (e.g., more than a hundred, more than five hundred, more than a thousand, or multiple thousands) of conductive connections. This arrangement can inhibit clock skew between the two logic dies, which can reduce a complexity and/or improve performance of a package including the two logic dies.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered exemplary in nature since many other architectures can be implemented to achieve the same functionality.

In some examples, all or a portion of example system 100 in FIG. 1 or example semiconductor device 200 can represent portions of a cloud-computing or network-based environment. Cloud-computing environments can provide various services and applications via the Internet. These cloud-based services (e.g., software as a service, platform as a service, infrastructure as a service, etc.) can be accessible through a web browser or other remote interface. Various functions described herein can be provided through a remote desktop environment or any other cloud-based computing environment.

In various implementations, all or a portion of example system 100 in FIG. 1 or example semiconductor device 200 in FIG. 2 can be used to facilitate multi-tenancy within a cloud-based computing environment. In other words, the systems and devices described herein can be used to configure a computing system (e.g., a server) to facilitate multi-tenancy for one or more of the functions described herein. For example, one or more of the systems and devices described herein can be used to program a server to enable two or more clients (e.g., customers) to share an application that is running on the server. A server programmed in this manner can share an application, operating system, processing system, and/or storage system among multiple customers (i.e., tenants). One or more of the systems and devices described herein can also be used to partition data and/or configuration information of a multi-tenant application for each customer such that one customer cannot access data and/or configuration information of another customer.

According to various implementations, all or a portion of example system 100 in FIG. 1 or example semiconductor device 200 in FIG. 2 can be implemented within a virtual environment. For example, the data described herein can reside and/or execute within a virtual machine. As used herein, the term “virtual machine” can generally refer to any operating system environment that is abstracted from computing hardware by a virtual machine manager (e.g., a hypervisor).

In some examples, all or a portion of example system 100 in FIG. 1 or example semiconductor device 200 in FIG. 2 can represent portions of a mobile computing environment. Mobile computing environments can be implemented by a wide range of mobile computing devices, including mobile phones, tablet computers, e-book readers, personal digital assistants, wearable computing devices (e.g., computing devices with a head-mounted display, smartwatches, etc.), variations or combinations of one or more of the same, or any other suitable mobile computing devices. In some examples, mobile computing environments can have one or more distinct features, including, for example, reliance on battery power, presenting only one foreground application at any given time, remote management features, touchscreen features, location and movement data (e.g., provided by Global Positioning Systems, gyroscopes, accelerometers, etc.), restricted platforms that restrict modifications to system-level configurations and/or that limit the ability of third-party software to inspect the behavior of other applications, controls to restrict the installation of applications (e.g., to only originate from approved application stores), etc. Various functions described herein can be provided for a mobile computing environment and/or can interact with a mobile computing environment.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device comprising:
a first logic die comprising:
a clock source configured to generate a clock signal; and
a first clock mesh for receiving the clock signal from the clock source;
a second logic die stacked over the first logic die, the second logic die comprising:
a second clock mesh for receiving the clock signal from the clock source; and
a plurality of conductive connections between the first clock mesh and the second clock mesh to transmit the clock signal from the first clock mesh to the second clock mesh.

2. The semiconductor device of claim 1, wherein the plurality of conductive connections comprises conductive vias electrically connecting the first clock mesh to the second clock mesh.

3. The semiconductor device of claim 2, wherein the conductive vias are positioned in and pass through at least a portion of the first logic die.

4. The semiconductor device of claim 2, wherein the conductive vias are electrically connected to respective conductive bond pads.

5. The semiconductor device of claim 4, wherein the first logic die comprises the conductive vias and the second logic die comprises the conductive bond pads.

6. The semiconductor device of claim 1, wherein the clock source comprises a phase-locked loop clock source.

7. The semiconductor device of claim 1, wherein the second logic die further comprises a local clock source configured to generate a test clock signal for testing of the second logic die separate from the first logic die.

8. The semiconductor device of claim 7, wherein the second logic die further comprises a tri-state driver between the local clock source and the second clock mesh.

9. The semiconductor device of claim 1, wherein the plurality of conductive connections comprises at least one hundred conductive connections between the first clock mesh and the second clock mesh.

10. The semiconductor device of claim 1, wherein the plurality of conductive connections comprises at least one thousand conductive connections between the first clock mesh and the second clock mesh.

11. The semiconductor device of claim 1, wherein:
the first logic die further comprises:
a first plurality of state storage elements configured for receiving the clock signal from the first clock mesh; and
at least one first level of gating between the first clock mesh and the first plurality of state storage elements; and
the second logic die further comprises:
a second plurality of state storage elements configured for receiving the clock signal from the second clock mesh; and
at least one second level of gating between the second clock mesh and the second plurality of state storage elements.

12. The semiconductor device of claim 11, wherein:
the first plurality of state storage elements comprises a first plurality of flip-flop elements; and
the second plurality of state storage elements comprises a second plurality of flip-flop elements.

13. The semiconductor device of claim 1, wherein the first logic die further comprises a tri-state driver between the clock source and the first clock mesh, wherein the tri-state driver is deactivated during testing of the first logic die separate from the second logic die and is activated during operation of the first logic die and second logic die stacked over the first logic die to boost the clock signal for use by both the first logic die and the second logic die.

14. A computer system, comprising:
a memory device configured to store computer-executable instructions; and
a semiconductor device in communication with the memory device and configured to execute the computer-executable instructions, the semiconductor device comprising:
a first logic die, comprising:
a clock source configured to generate a clock signal;
a first plurality of state storage elements; and
a first clock mesh for distributing the clock signal from the clock source to the first plurality of state storage elements;
a second logic die stacked over the first logic die, the second logic die comprising:
a second plurality of state storage elements; and
a second clock mesh for distributing the clock signal from the clock source to the second plurality of state storage elements; and
a plurality of conductive connections between the first clock mesh and the second clock mesh to transmit the clock signal from the first clock mesh to the second clock mesh.

15. The computer system of claim 14, wherein the plurality of conductive connections comprises conductive vias passing through at least a portion of the first logic die and conductive bond pads of the second logic die.

16. The computer system of claim 14, wherein the first plurality of state storage elements comprises a first plurality of flip-flop elements and the second plurality of state storage elements comprises a second plurality of flip-flop elements.

17. The computer system of claim 14, wherein the plurality of conductive connections comprises an array of at least one hundred conductive connections.

18. A method of fabricating a semiconductor device, the method comprising:
stacking and bonding a first logic die including a clock source and a first clock mesh with a second logic die including a second clock mesh; and
electrically coupling the first clock mesh to the second clock mesh with a plurality of conductive connections to transmit a clock signal from the clock source and first clock mesh to the second clock mesh.

19. The method of claim 18, wherein electrically coupling the first clock mesh to the second clock mesh with the plurality of conductive connections comprises electrically shorting the first clock mesh to the second clock mesh with an array of conductive connections.

20. The method of claim 19, wherein electrically shorting the first clock mesh to the second clock mesh with an array of conductive connections comprises electrically shorting the first clock mesh to the second clock mesh with an array of at least one hundred conductive vias passing through at least a portion of the first logic die.
